(19) United States
(12) Patent Application Publication
(10) Pub. No.: US 2010/0039770 A1
(43) Pub. Date: Feb. 18, 2010

(54) Pneumatic presssure wedge

(76) Inventors: Paul A. Danello, Franklin, MA (US); Michael P. Martinez, Worcester, MA (US); Russell D. Belanger, Tyngsborough, MA (US); Joaquim A. Bento, Marlborough, MA (US); Joseph R. Ellsworth, Worcester, MA (US)

Correspondence Address: Iandiorio Teska & Coleman, 260 Bear Hill Road, Waltham, MA, 02451, US

(21) Appl. No.: 12/228,699

(22) Filed: Aug. 15, 2008

(51) Int. Cl. H05K 7/20

(52) U.S. Cl. 361/691

(57) ABSTRACT

An electronic subsystem such as an array of radar transmit/receive microwave modules are associated with (e.g., base mounted to) spaced heat sinks. There is an electronic module on each side of each heat sink and an inflatable bladder or “pneumatic pressure wedge” between adjacent heat sinks biases a pair of electronic modules against their respective heat sinks.

### FIELD OF THE INVENTION

The subject invention relates to cooling electronic modules which, in one particular example, are radar transmit/receive integrated microwave modules.

### BACKGROUND OF THE INVENTION

Electronic circuits are traditionally cooled using a variety of methods. In certain radar systems, there are hundreds of electronic modules called transmit/receive integrated microwave modules (TRIMMs). Each such module includes several transmit/receive units, polarizers, and power supplies between spaced side rails which are cooled via coolant flowing in manifold ribs in an equipment rack housing the modules.

There is a tendency to drive the microwave integrated circuitry at higher and higher power levels which generates additional heat. See co-pending U.S. patent application Ser. No. 11/716,864 filed Mar. 12, 2007 incorporated herein by this reference. At the same time, many conventional cooling methods cannot be utilized for the TRIMM because they must be easily and quickly removed from their respective equipment racks for servicing.

In the edge mounted configuration, the side rails of each TRIMM are held against the cooling manifold ribs of the equipment rack using wedge locks so individual TRIMMs can be removed from and inserted into the equipment racks. Studies have shown that at higher power levels the edge mounted configuration may not provide sufficient cooling.

Some radar systems use a flange mounted configuration in an attempt to better cool the TRIMMs. With higher power levels, however, flange cooling may not be sufficient in such a design.

Base mounting of a TRIMM is a possibility wherein the base of a TRIMM is fastened to a heat sink using fasteners or wedge locks. But, fasteners are undesirable because of the time required to install and remove a TRIMM from its heat sink. Fasteners also do not ensure sufficient heat transfer since good contact between the module and the heat sink is only present in a very localized region around each fastener. Wedge locks suffer from the same problems. Another common problem with fasteners such as bolts and wedge locks is the difficulty in determining whether or not the fastener was properly torqued during installation or has come loose during operation. The contact pressure using a fastener or a wedge lock can be very low and unpredictable at locations away from the fastener region. The result is a lower thermal efficiency resulting in reduced performance and lower reliability. Moreover, the packing density associated with some radar system modules makes it difficult to use fasteners and/or wedge locks.

### BRIEF SUMMARY OF THE INVENTION

It is therefore an object of this invention to provide a new electronic module cooling system and method.

It is a further object of this invention to provide such a system and method which is particularly useful in connection with radar transmit/receive integrated microwave modules.

It is a further object of this invention to provide such a system and method which allows individual electronic modules to be quickly installed and removed for service.

It is a further object of this invention to provide such a system and method which uniformly biases each module against its respective heat sink.

It is a further object of this invention to provide such a system and method which is reliable, simple in design, and relatively inexpensive.

It is a further object of this invention to provide such a system and method which optimizes the thermal efficiency of a base cooled electronic module.

It is a further object of this invention to provide such a system which is light weight.

It is a further object of the subject invention to provide such a system and method which can be used to cool electronic components other than radar modules.

The subject invention results from the realization that a pneumatic pressure wedge which, when inflated, creates a good electronics packaging thermal interface to a base cooled surface and which, when deflated, allows the electronics module to be removed for servicing.

This invention features an electronic subsystem comprising spaced heat sinks, an electronic module on each side of each heat sink, and an inflatable bladder between adjacent heat sinks biasing a pair of electronic modules against their respective heat sinks. Typically, an array of electronic module pairs are each associated with a heat sink and an inflatable bladder is located between adjacent electronic modules biasing them against their respective heat sinks.

In one example, each electronic module is a radar transmit/receive integrated microwave module and the heat sinks are associated with a cooling manifold. Preferably, each bladder is made of an elastomer. In one example, each bladder is rectangular and has a planar, low profile configuration. The preferred bladder may include at least two internal cavities therein. Each bladder also typically includes a fitting for inflating each cavity and a conduit is connected to each bladder fitting. A compressor is connected to each conduit and an expansion tank connected to each conduit. A pressure sensor associated with each conduit is for sensing the pressure in each conduit and a processing module responsive to the pressure sensors is configured to control the compressor to maintain a predetermined pressure in the bladders.

The electronic subsystem may further include a rack for mounting each bladder with a mounting feature. In the preferred embodiment, each rack includes a track and each bladder includes a rail received in the track.

One electronic subsystem in accordance with the subject invention includes a set of bladders inflatable to bias electronic modules against their respective heat sinks, at least one inflation fitting for each bladder, a conduit connected to the bladder inflation fittings, and a compressor connected to the conduit for inflating the set of bladders.

The subject invention also features a bladder comprising a sealed expandable member with at least one cavity therein and configured to bias an electronic module against a heat sink. A fitting is in fluid communication with the cavity for inflating the expandable member to bias the electronic module against the heat sink and for deflating the sealed expandable member in order to service the electronic module.

The member may be made of an elastomer and it is typically rectangular with a planar, low profile configuration. In one example, there are two internal cavities. The bladder may include at least one mounting feature and in the preferred embodiment there are top and bottom rails for mounting the bladder member in spaced racks.

The subject invention also features a new method of cooling an electronic module. The typical method includes associating the module with a heat sink, installing a deflated bladder proximate the module, and inflating the bladder to bias the module against the heat sink. One method of cooling an array of electronic modules in accordance with the subject invention includes associating each module with one side of a heat sink, installing a deflated bladder between adjacent heat sinks, and inflating the bladders to bias a pair of electronic modules against their respective heat sinks.

The subject invention, however, in other embodiments, need not achieve all these objectives and the claims hereof should not be limited to structures or methods capable of achieving these objectives.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic three-dimensional top view showing an example of a radar transmit/receive integrated microwave module;

FIG. 2 is a schematic cross-sectional end view showing how an array of modules of the type shown in FIG. 1 are cooled in an edge mounted configuration;

FIG. 3 is a highly schematic three-dimensional front view showing another type of a radar transmit and receive integrated microwave module attached to a cooling manifold in a flange mounted configuration;

FIG. 4 is a highly schematic cross-sectional view showing how inflatable bladders in accordance with the subject invention can be used to bias electronic modules into engagement with their respective heat sinks;

FIG. 5A is a schematic three-dimensional front exploded view showing a pneumatic pressure wedge in accordance with an example of the subject invention for use with a radar transmit/receive module base mounted to a cooling manifold;

FIG. 5B is a schematic three-dimensional front view showing the pneumatic pressure wedge of FIG. 5A now installed and creating a uniform pressure at the thermal interface between an electronics module and the cooling manifold;

FIG. 6 is a three-dimensional schematic view showing a particular example of an inflatable bladder in accordance with the subject invention;

FIG. 7A is a schematic three-dimensional front view of the inflatable bladder showing FIG. 6;

FIG. 7B is a schematic side view of the inflatable bladder shown in FIG. 6 and 7A;

FIG. 8A is a schematic cross-sectional view of a portion of the inflatable bladder shown in FIGS. 6-7 in its inflated configuration;

FIG. 8B is a schematic cross-sectional side view of the inflatable bladder shown in FIGS. 6-7 in its deflated configuration;

FIG. 9 is a schematic three-dimensional front view showing an array of inflatable bladders used in connection with an electronic module equipment rack in accordance with the subject invention; and

FIG. 10 is a block diagram showing an exemplary system for controlling the pressure of one or more inflatable bladders in accordance with the subject invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

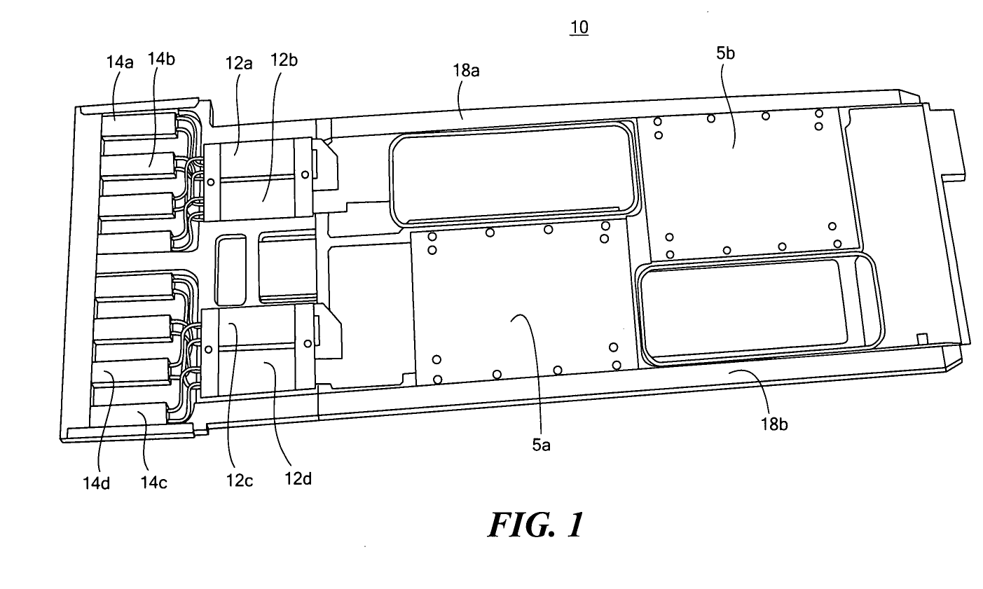

FIG. 1 shows electronics module 10 in accordance with an example associated with the subject invention. In this example, module 10 is a radar transmit and receive integrated microwave module or “TRIMM” with transmit/receive units 12a-12d, polarizers 14a-14d, and power supplies (DC/DC converters) 5a and 5b.

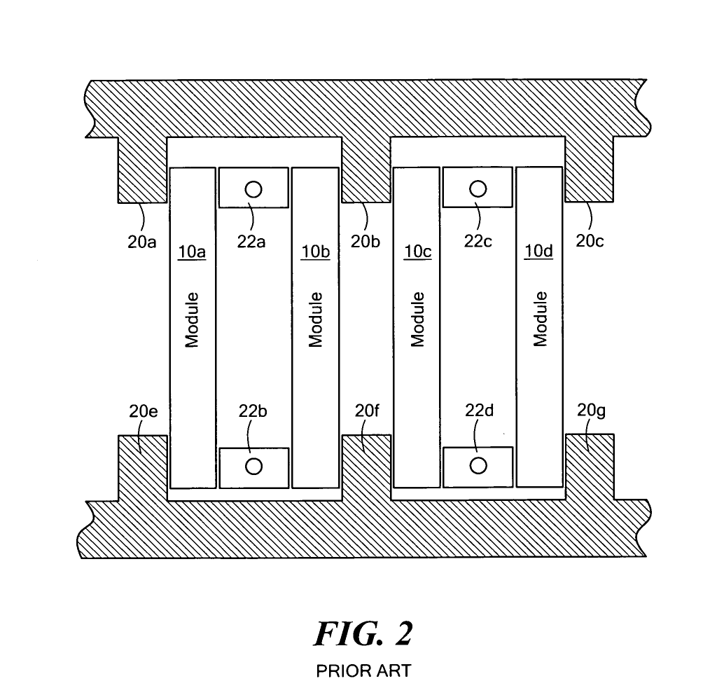

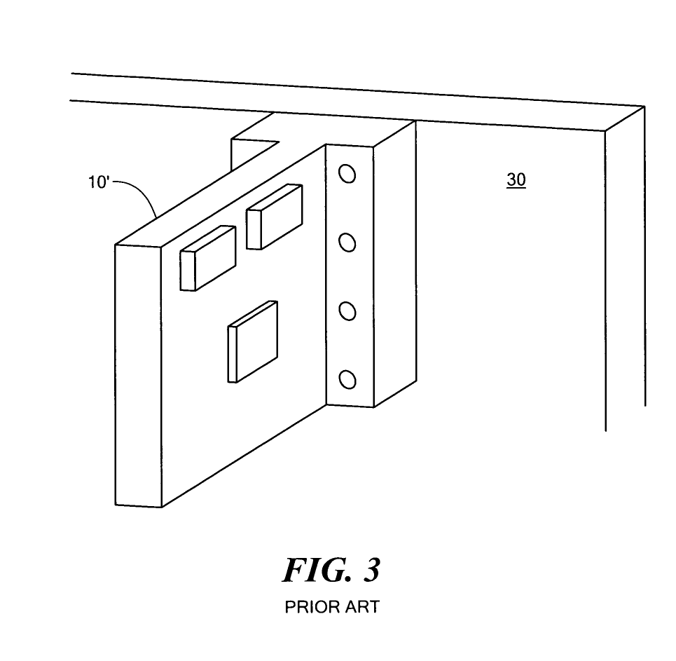

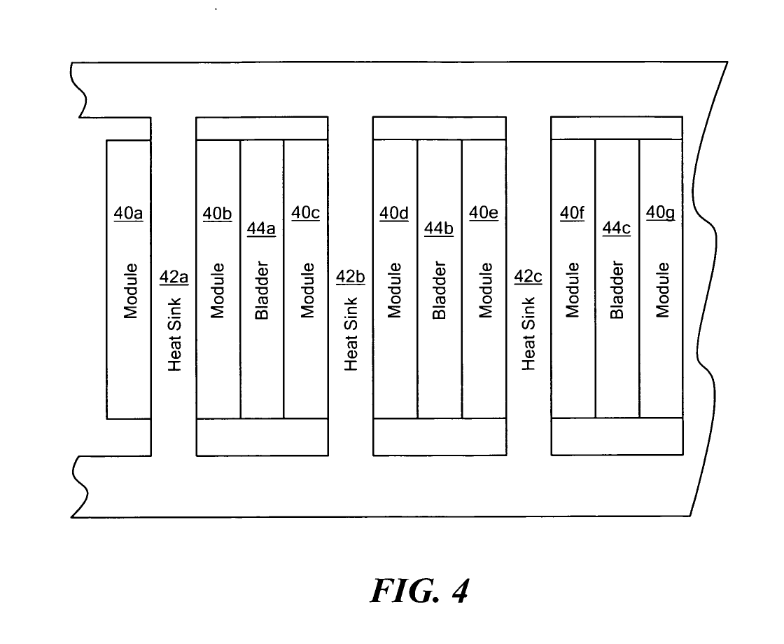

In the prior art, the edge rails 18a and 18b of module 10 were cooled via the edge mounted configuration shown in FIG. 2. The edge rails of each module 10a-10d are held against the cooling manifold ribs 20a-20g of the equipment rack housing the modules using wedge locks 22a-22d between adjacent module pairs. Coolant typically flows in the ribs. FIG. 3 shows a flange mounted configuration where module 10′ is fastened to cooling manifold 30.

As delineated in the Background section above, these prior configurations may not provide sufficient cooling when the power levels of the radar system are increased resulting in significantly increased heat flux.

In accordance with the subject invention, electronic modules 40a-40g are base mounted to heat sinks 42a-42c as shown in an array such that modules 40a and 40b are associated with opposite sides of heat sink 42a, modules 40c and 40d are associated with opposite sides of heat sink 42b, and modules 40e and 40f are associated with opposite sides of heat sink 42c. Rather than using wedge locks or fasteners, however, inflatable bladder 44a between modules 40b and 40c biases module 40b against one side of heat sink 42a and also biases module 40c against one side of heat sink 42b.

The inflatable bladder allows for a highly uniform pressure distribution from the electronics package to the cooling surface. The air inflatable bladder compresses the electronics package against the cooling surface and the bladder is able to conform to the shape of the package to apply a uniform pressure at the thermal interface. Experimental results show that the bladder provided very uniform and a consistent pressure distribution. The preferred bladder has a very low profile and is compatible with compact, efficient electronics packaging schemes and can be inflated remotely from a convenient location away from the area of which the pressure is applied. The ability of the bladder to conform to the shape of the package allows for a large z-axis tolerance compensation. When compared to existing fastening methods, the bladder concept disclosed herein is also light weight and inexpensive. In a similar manner, bladder 44b biases module 40d against one surface of heat sink 42b and also biases module 40e against one side of heat sink 42c. Bladder 44c biases module 40f against the opposite side of heat sink 42c and biases module 40g against its heat sink (not shown).

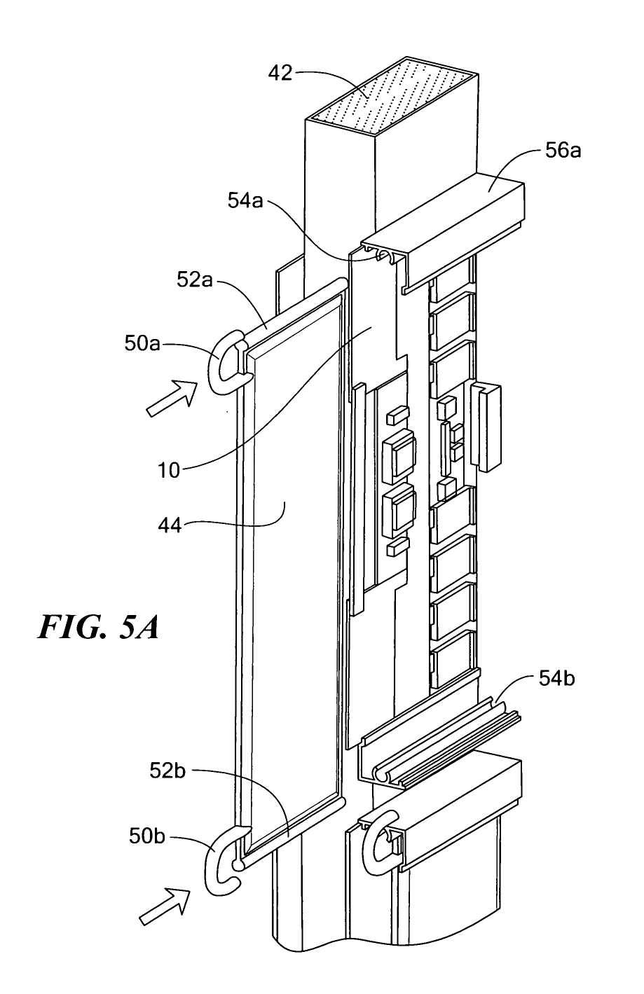

FIGS. 5A-5B show particular TRIMM module 10 adjacent heat sink 42 (here a cooling manifold with a coolant flowing therein) and a particular configuration for bladder 44. Bladder 44 is an expandable member made of an elastomer such as layers of EPDM. Bladder 44 has a planar configuration with a heat/pressure seal around its perimeter. In this example, there are two lengthwise internal cavities each inflated by its own fitting 50a and 50b. Bladder 44 also includes top and bottom rails 52a and 52b received in tracks 54a and 54b, respectively, of racks (see rack 56a) mounted on cooling manifold 42. In this way, the bladders are easy to install and remove.

When installed and inflated as shown in FIG. 5B, bladder 44 biases electronic module 10 against cooling manifold 42 creating a uniform pressure at the thermal interface between module 10 and cooling manifold 42. Typically, a cover or some kind of protective feature or standoff (not shown) is associated with module 10 to protect the circuits thereof against damage when bladder 44 is inflated. FIGS. 5A-5B also show an electronic module on the opposite side of manifold 42 and another module and a bladder beneath bladder 10.

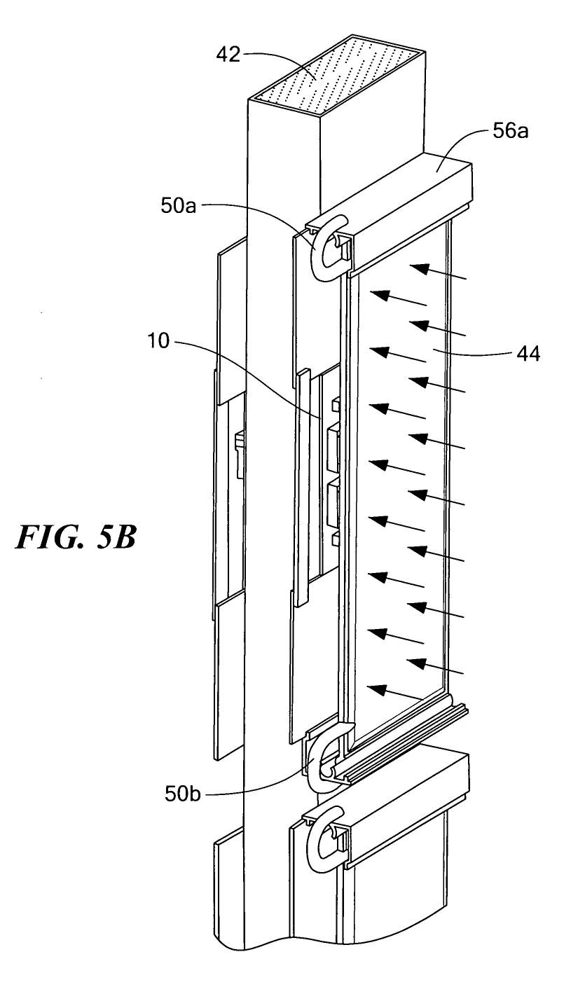

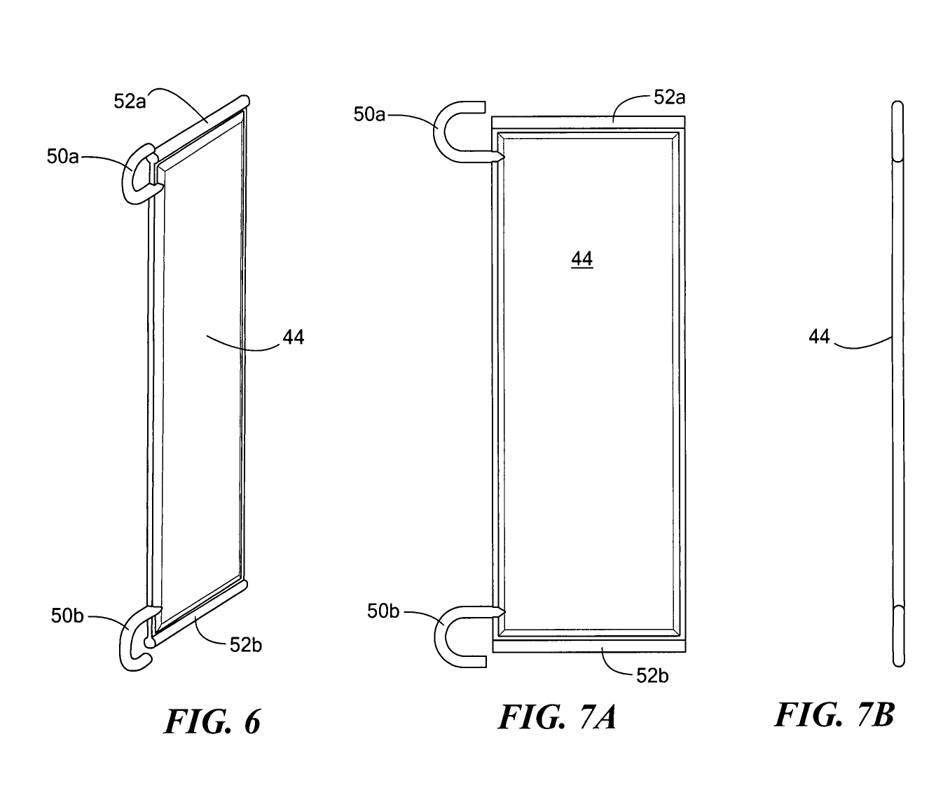

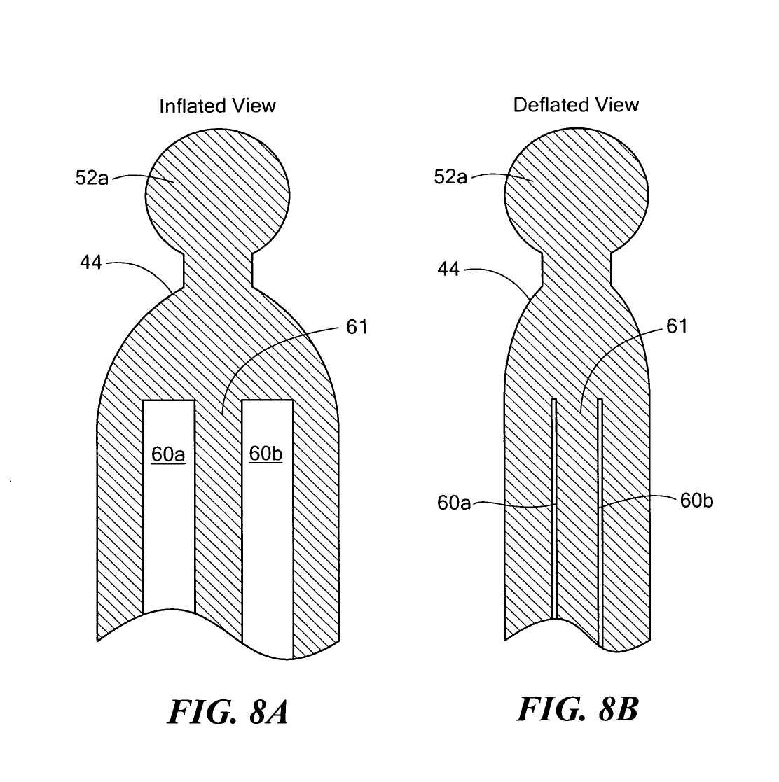

In the example shown in FIGS. 6-8, bladder 44 is 5.50 inches wide, 16 inches tall, and 0.38 inches thick when deflated. The bladder was 0.5 inches thick when inflated and includes opposing flat walls for providing a uniform pressure to the electronic modules. FIG. 8A shows dual internal cavities 60a and 60b for reliability purposes. Top fitting 50a, FIG. 7A is in fluid communication with cavity 60a and bottom fitting 50b is connected to cavity 60b. Both cavities extend length and widthwise across the extent of the bladder and the cavities are separated by the material of the bladder as shown at 61 in FIGS. 8A-8B.

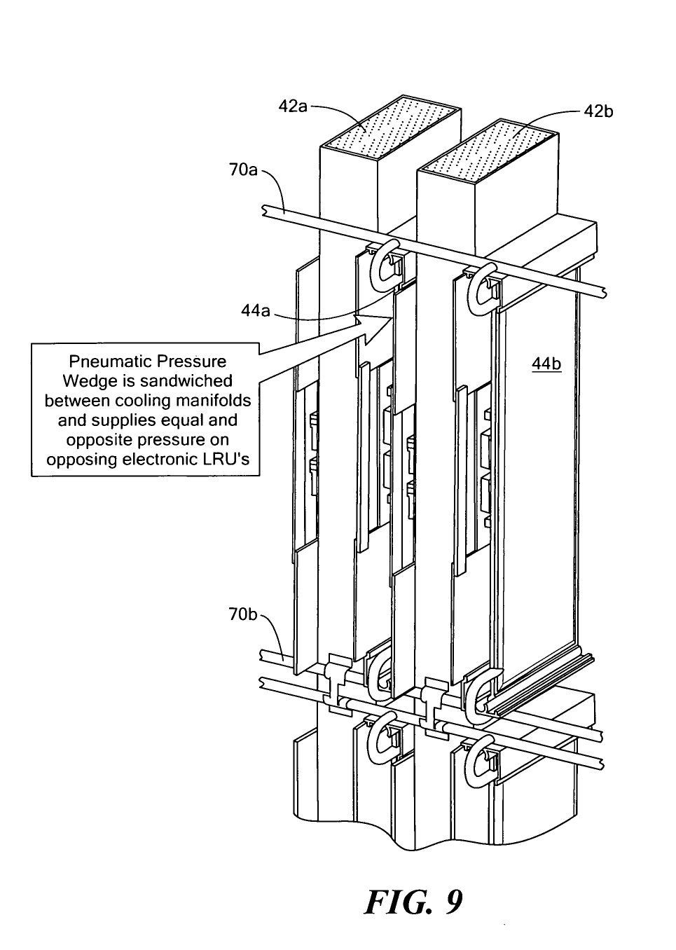

FIG. 9 shows conduit 70a connected to multiple bladders via their top fittings and conduit 70b also connected to multiple bladders via their bottom fittings. Such a configuration provides for a redundancy since conduit 70b will still inflate one cavity of each bladder 44a, 44b if air pressure in conduit 70a is not available. The bladders, in turn, when inflated, supply equal and opposite pressure to the electronics modules on each side of each bladder. And, all the bladders of a particular equipment rack cavity can be inflated and deflated at the same time. When the bladders are deflated, the electronic modules can be removed for servicing or replacement.

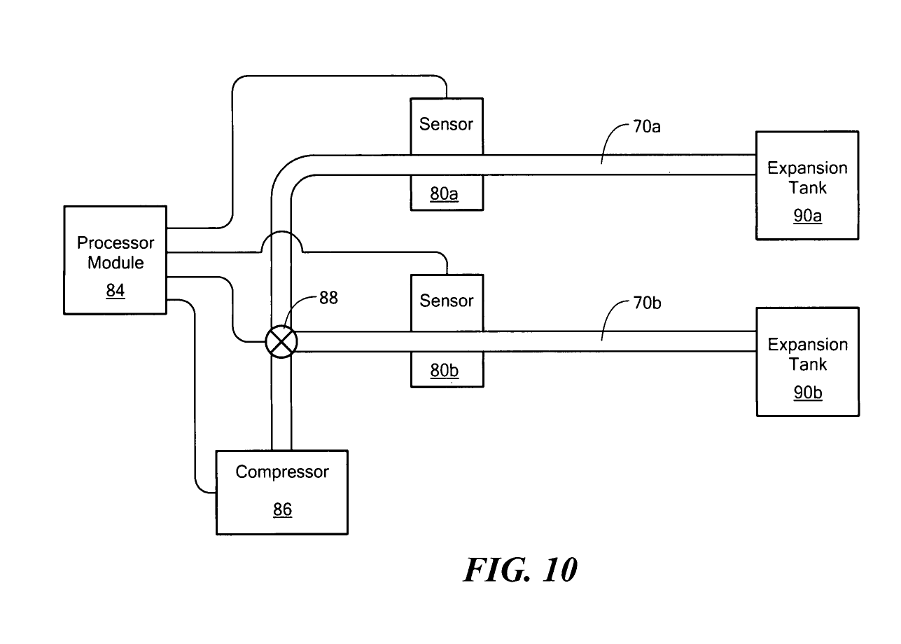

To account for differences in ambient temperature, FIG. 10 shows pressure sensors 80a and 80b associated with conduit 70a and 70b, respectively. In one example, suppose 20 psi is desired in each bladder but a cold day results in only 10 psi in each bladder. Processing module 84 is responsive to pressure sensors 80a and 80b and is configured to activate compressor 86 to pump air until 20 psi is detected by sensors 80a and 80b. Valve 88 may also be controlled by processing module 84 to independently control the pressure in conduits 70a and 70b. Expansion tanks 90a and 90b are configured to prevent an over pressurization condition in the bladders on extremely hot days. Alternatively, processing module 84 could activate valves in conduit 70a and 70b to bleed off pressure. In addition, or alternatively, processing module 84 can simply indicate via an electronic signal or a transmitted message or other alarm output that a low or high pressure condition exists. In another version, a pressure transducer in each inflatable bladder can be configured to indicate any reduction in performance and provide an electronic signal for maintenance. In testing, the effective interface heat transfer coefficient exceeded 1,000 BTU/hr ft²F and proved 10 to 20 psi is sufficient.

In the examples discussed herein, the electronics modules disclosed are specific TRIMM modules in an array and the heat sinks are cooling manifolds configured in a cavity configuration for an equipment rack associated with a radar system.

In other examples, however, any heat source can be biased against a heat sink of varying designs using the bladder concept hereof. As such, the configuration of the bladder may vary from the design shown in FIG. 6. The subject invention applies to any method of cooling electronic modules where each module is associated with a heat sink and a bladder is used in an inflated configuration to bias the module against the heat sink.

Thus, although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the

1. An electronic subsystem comprising:
spaced heat sinks;
an electronic module on each side of each heat sink; and
an inflatable bladder between adjacent heat sinks biasing a pair of electronic modules against their respective heat sinks.

2. The electronic subsystem of claim 1 in which each electronic module is a radar transmit/receive integrated microwave module.

3. The electronic subsystem of claim 1 in which the heat sinks are associated with a cooling manifold.

4. The electronic subsystem of claim 1 in which each bladder is made of an elastomer.

5. The electronic subsystem of claim 1 in which each bladder is rectangular and has a planar, low profile configuration.

6. The electronic subsystem of claim 1 in which each bladder includes at least two internal cavities therein.

7. The electronic subsystem of claim 6 in which each bladder includes a fitting for independently inflating each cavity.

8. The electronic subsystem of claim 7 further including a conduit connected to each bladder fitting.

9. The electronic subsystem of claim 8 further including a compressor connected to each conduit.

10. The electronic subsystem of claim 9 further including an expansion tank connected to each conduit.

11. The electronic subsystem of claim 9 further including a pressure sensor associated with each conduit for sensing the pressure in each conduit.

12. The electronic subsystem of claim 11 further including a processing module responsive to the pressure sensors and configured to control the compressor to maintain a predetermined pressure in the bladders.

13. The electronic subsystem of claim 1 further including a rack for mounting each bladder.

14. The electronic subsystem of claim 13 in which each bladder includes a mounting feature.

15. The electronic subsystem of claim 14 in which each rack includes a track and each bladder includes a rail received in the track of the rack.

16. An electronic subsystem comprising:
a set of bladders inflatable to bias electronic modules against their respective heat sinks;
at least one inflation fitting for each bladder;
a conduit connected to the bladder inflation fittings; and
a compressor connected to the conduit for inflating the set of bladders.

17. The electronic subsystem of claim 16 further including an expansion tank connected to the conduit.

18. The electronic subsystem of claim 16 further including a pressure sensor associated with the conduit for sensing the pressure in the conduit.

19. The electronic subsystem of claim 18 further including a processing module responsive to the pressure sensor and configured to control the compressor to maintain a predetermined pressure in the bladders.

20. The electronic subsystem of claim 16 further including a rack for mounting each bladder.

21. The electronic subsystem of claim 20 in which each bladder includes a mounting feature securable in the rack.

22. A bladder comprising:
a sealed expandable member with at least one cavity therein and configured to bias an electronic module against a heat sink; and
a fitting in fluid communication with the cavity for inflating the expandable member to bias the electronic module against the heat sink and for deflating the sealed expandable member in order to service the electronic module.

23. The bladder of claim 22 in which the member is made of an elastomer.

24. The bladder of claim 22 in which the member is rectangular and has a planar, low profile configuration.

25. The bladder of claim 22 in which the member includes at least two internal cavities therein.

26. The bladder of claim 22 which the member includes at least one mounting feature.

27. The bladder of claim 22 further including top and bottom rails for mounting the member.

28. An electronic subsystem comprising:
an array of electronic module pairs each associated with a heat sink; and
an inflatable bladder between adjacent electronic modules biasing them against their respective heat sinks.

29. A method of cooling an electronic module, the method comprising:
associating the module with a heat sink;
installing a deflated bladder proximate the module; and
inflating the bladder to bias the module against the heat sink.

30. A method of cooling an array of electronic modules, the method comprising:
associating each module with one side of a heat sink;
installing a deflated bladder between adjacent heat sinks; and
inflating the bladders to bias a pair of electronic modules against their respective heat sinks.
